(19) United States
(12) Patent Application Publication
(10) Pub. No.: US 2022/0115385 A1
(43) Pub. Date: Apr. 14, 2022

(54) METHOD FOR MANUFACTURING SEMICONDUCTOR DEVICE SEMICONDUCTOR DEVICE AND MEMORY

(71) Applicant: CHANGXIN MEMORY TECHNOLOGIES, INC., Hefei City (CN)

(72) Inventors: Shiran ZHANG, Hefei (CN); Zhengqing SUN, Hefei (CN); Youquan YU, Hefei (CN)

(21) Appl. No.: 17/469,407

(22) Filed: Sep. 8, 2021

Related U.S. Application Data
(63) Continuation of application No. PCT/CN2021/105547, filed on Jul. 9, 2021.

(30) Foreign Application Priority Data
Oct. 10, 2020 (CN) 202011077071.3

(51) Int. Cl. H01L 27/108; H01L 29/423; H01L 21/8238

(52) U.S. Cl. CPC H01L 27/10897; H01L 21/823857; H01L 29/42364

(57) ABSTRACT

The disclosure relates to a method for manufacturing a semiconductor device, a semiconductor device and a memory, and belongs to the field of semiconductor technologies. The method for manufacturing the semiconductor device includes: a semiconductor substrate is provided; a shallow trench isolation structure and a plurality of grooves arranged at intervals are formed on the semiconductor substrate, and a substrate bulge is formed between two adjacent grooves; a gate oxide layer is deposited on the surface of the semiconductor substrate, and the gate oxide layer covers the grooves and the substrate bulge; a gate structure is formed on the gate oxide layer, the gate structure includes a first gate structure and a second gate structure, and the first gate structure covers the surface of the substrate bulge; and a source electrode and a drain electrode are formed in the semiconductor substrate.

### CROSS-REFERENCE TO RELATED APPLICATIONS

This is a continuation of International Application No. PCT/CN2021/105547, filed on Jul. 9, 2021 and entitled “Method for Manufacturing Semiconductor Device, Semiconductor Device and Memory”, which claims priority to Chinese patent application No. 202011077071.3, filed on Oct. 10, 2020 and entitled “Method for Manufacturing Semiconductor Device, Semiconductor Device and Memory”. The disclosures of International Application No. PCT/CN2021/105547 and Chinese patent application No. 202011077071.3 are hereby incorporated by reference in their entireties.

### TECHNICAL FIELD

The disclosure relates to the field of semiconductor technologies, and in particular to a method for manufacturing a semiconductor device, a semiconductor device and a memory.

### BACKGROUND

With the continuous development of semiconductor integrated circuit device technologies, how to optimize the process flow is the main route to effectively improve the production efficiency and reduce the production and operation cost of a company. A Dynamic Random Access Memory (DRAM) is a commonly used semiconductor memory device, which includes a plurality of repeated memory cells, and each memory cell includes a capacitor and a transistor.

Complementary metal oxide semiconductor transistors have been widely applied in various semiconductor integrated circuit devices. For different device performances and product demands, the Complementary Metal Oxide Semiconductor (CMOS) transistors meeting different capacitance parameters are required. At present, the different capacitance parameters of CMOS and the electrical demands of a corresponding device are met by changing the thickness of a gate oxide layer and forming the gate oxide layer with different thickness. However, this technique is complex and higher in cost. In addition, when the gate oxide layer is adjusted to a low thickness, problems such as electric leakage easily occurs in the semiconductor device.

It is to be noted that information disclosed in the above background is only used to enhance the understanding of the background of the disclosure, and therefore may include information that does not constitute the related art known to those of ordinary skill in the art.

### SUMMARY

The purpose of the disclosure is to provide a method for manufacturing a semiconductor device, a semiconductor device and a memory device.

According to a first aspect of the disclosure, a method for manufacturing a semiconductor device is provided, including the following operations.

A semiconductor substrate is provided.

A shallow trench isolation structure and a plurality of grooves arranged at intervals are formed on the semiconductor substrate, and a substrate bulge is formed between two adjacent ones of the grooves.

A gate oxide layer is deposited on the surface of the semiconductor substrate, and the gate oxide layer covers the grooves and the substrate bulge.

A gate structure is formed on the gate oxide layer, the gate structure includes a first gate structure and a second gate structure, and the first gate structure covers the surface of the substrate bulge.

A source electrode and a drain electrode are formed in the semiconductor substrate, and the gate oxide layer, the gate structure, the source electrode and the drain electrode form a transistor device.

According to a second aspect of the disclosure, a semiconductor device is provided, and the semiconductor device includes a semiconductor substrate, a gate oxide layer, a gate structure, a source electrode and a drain electrode.

The semiconductor substrate includes a shallow trench isolation structure and a plurality of grooves arranged at intervals, and a substrate bulge is formed between two adjacent ones of the grooves.

The gate oxide layer is deposited on the surface of the semiconductor substrate, and the gate oxide layer covers the grooves and the substrate bulge.

The gate structure is formed on the gate oxide layer, the gate structure includes a first gate structure and a second gate structure, and the first gate structure covers the surface of the substrate bulge.

The source electrode and the drain electrode are formed in the semiconductor substrate.

According to a third aspect of the disclosure, a memory is provided, the memory includes an array area and a peripheral area, and the peripheral area includes a semiconductor device manufactured according to the manufacturing method in the first aspect.

It should be understood that general description above and the detailed description below are only illustrative and explanatory and do not restrict the disclosure.

### BRIEF DESCRIPTION OF THE DRAWINGS

The drawings herein are incorporated into the specification and constitute part of this specification, show the embodiment conforming to the disclosure, are used together with the specification to explain the principles of the disclosure. It is apparent that the drawings described below merely illustrate some embodiments of the embodiments of the disclosure. Those ordinarily skilled in the art can obtain other accompanying drawings without creative labor on the basis of those accompanying drawings.

FIG. 1 is a flow schematic diagram of a method for manufacturing a semiconductor device according to some embodiments of the disclosure.

FIG. 2 is a structural schematic diagram of a mask layer formed in a process for manufacturing a semiconductor device according to some embodiments of the disclosure.

FIG. 3 is a structural schematic diagram of an anti-reflection layer formed in a method for manufacturing a semiconductor device according to some embodiments of the disclosure.

FIG. 4 is a schematic diagram of a first photoetching layer formed in a method for manufacturing a semiconductor device according to some embodiments of the disclosure.

FIG. 5 is a structural schematic diagram of bulges formed in an anti-reflection layer in a process for manufacturing a semiconductor device according to some embodiments of the disclosure.

FIG. 6 is a structural schematic diagram of a second photoetching layer formed in a process for manufacturing a semiconductor device according to some embodiments of the disclosure.

FIG. 7 is a structural schematic diagram of a groove and an isolation channel formed in a process for manufacturing a semiconductor device according to some embodiments of the disclosure.

FIG. 8 is a structural schematic diagram of a dielectric layer formed in a process for manufacturing a semiconductor device according to some embodiments of the disclosure.

FIG. 9 is a structural schematic diagram of a shallow trench isolation structure formed in a process for manufacturing a semiconductor device according to some embodiments of the disclosure.

FIG. 10 is a structural schematic diagram of a gate oxide layer formed in a process for manufacturing a semiconductor device according to some embodiments of the disclosure.

FIG. 11 is a structural schematic diagram of a polycrystalline silicon layer formed in a process for manufacturing a semiconductor device according to some embodiments of the disclosure.

FIG. 12 is a structural schematic diagram of a barrier layer formed in a process for manufacturing a semiconductor device according to some embodiments of the disclosure.

FIG. 13 is a structural schematic diagram of a conductive metal layer formed in a process for manufacturing a semiconductor device according to some embodiments of the disclosure.

FIG. 14 is a structural schematic diagram of an insulation layer structure formed in a process for manufacturing a semiconductor device according to some embodiments of the disclosure.

FIG. 15 is a structural schematic diagram of a gate structure formed in a process for manufacturing a semiconductor device according to some embodiments of the disclosure.

FIG. 16 is a structural schematic diagram of an isolation layer formed in a process for manufacturing a semiconductor device according to some embodiments of the disclosure.

FIG. 17 is a schematic diagram of a semiconductor device manufactured according to some embodiments of the disclosure.

FIG. 18 is a structural schematic diagram of a memory according to some embodiments of the disclosure.

### DETAILED DESCRIPTION

The following completely describes the exemplary embodiments of with reference to the drawings. However, the exemplary embodiments can be implemented in various forms and should not be understood to be limited to the examples described herein. On the contrary, the provision of these embodiments makes the disclosure more comprehensive and complete and fully communicates the idea of the exemplary embodiments to those skilled in the art. The described features, structures, or characteristics may be combined in one or more embodiments in any appropriate manner. In the following description, many specific details are provided to give a full understanding of embodiments of this disclosure.

For clarity, the thickness of the areas and layers may have been exaggerated in the figure. The same drawing marks in the drawing indicate the same or similar structure, so their detailed description will be omitted.

The described features, structures, or characteristics may be combined in one or more embodiments in any appropriate manner. In the following description, many specific details are provided to give a full understanding of embodiments of this disclosure. However, those skilled in the art will be aware that the technical solution in the disclosure may be practiced without one or more of the specific details, or those other methods, components, materials and the like may be adopted. In other cases, public structures, materials, or operations are not specified or described in detail to avoid obfuscating the main technical creativity of the disclosure.

When a structure is “upper” of other structures, it may mean that this structure is integrally formed on other structures, or that this structure is “directly” on other structures or this structure is “indirectly” on other structures through another structure.

Terms “one”, “a/an”, “described” are used to indicate one or more elements/constituent distinctions/etc. Terms “include” and “have” are used to express an open sense of including and to indicate that additional elements/constituent distinctions/and the like may exist in addition to the listed elements/constituent distinctions/and the like. Terms “first” and “second” are used only as signs, not as a limitation on the number of their objects.

In the related art, the demand that the CMOS transistor device in the DRAM circuit requires different capacitance is usually met by forming the gate oxide layer with different thickness. However, this technique is complex and higher in cost. In addition, when the gate oxide layer is adjusted to a low thickness, problems such as electric leakage may occur in the semiconductor device.

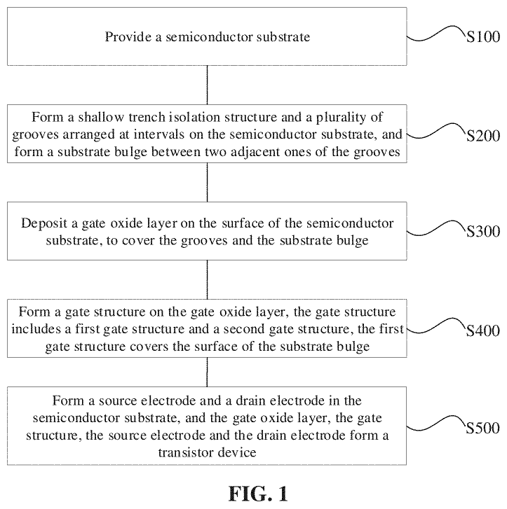

As shown in FIG. 1, the disclosure provides a method for manufacturing a semiconductor structure, including the following operations.

At S100, a semiconductor substrate is provided.

At S200, a shallow trench isolation structure and a plurality of grooves arranged at intervals are formed on the semiconductor substrate, and a substrate bulge is formed between two adjacent ones of the grooves.

At S300, a gate oxide layer is deposited on the surface of the semiconductor substrate, and the gate oxide layer covers the grooves and the substrate bulge.

At S400, a gate structure is formed on the gate oxide layer, the gate structure includes a first gate structure and a second gate structure, and the first gate structure covers the surface of the substrate bulge.

At S500, a source electrode and a drain electrode are formed in the semiconductor substrate, and the gate oxide layer, the gate structure, the source electrode and the drain electrode form a transistor device.

According to the method for manufacturing the semiconductor device provided by the disclosure, the shallow trench isolation structure and the plurality of grooves arranged at intervals are formed on the semiconductor substrate, and the substrate bulge is formed between two adjacent ones of the grooves. The gate oxide layer is deposited on the surface of the semiconductor substrate, and the gate oxide layer covers the grooves and the substrate bulge. The gate structure is formed on the gate oxide layer, the gate structure includes the first gate structure and the second gate structure, and the first gate structure covers the surface of the substrate bulge, so that the conductive channel of the first gate structure has a bending structure. The length of the gate oxide layer and the conductive channel extends in a longitudinal direction (a direction perpendicular to the semiconductor substrate), thus providing a transistor device, for example, a CMOS transistor, with different capacitance parameters. In addition, in the method for manufacturing the semiconductor device provided by the disclosure, the formed gate structure has an unchanged width in a horizontal direction (a direction parallel to the semiconductor substrate), and the conductive channel has an stretched length in a longitudinal direction, so that the short-channel effect of the transistor device may be effectively improved, thereby helping meet the demands of reduced size and high-density arrangement of the transistor device.

The method for manufacturing the semiconductor device provided by the disclosure is described in detail in combination with the drawings.

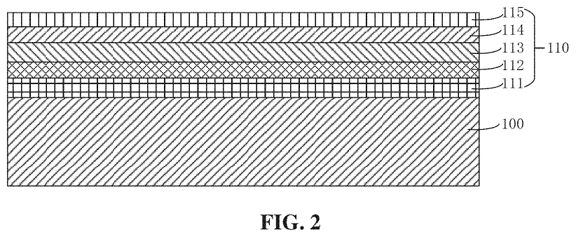

As shown in FIG. 2, in S100, a semiconductor substrate 100 is provided. The semiconductor substrate 100 may select a silicon substrate or a substrate made of silicon, germanium, silicon germanium compound and other suitable semiconductor substrate materials. In some embodiments of the disclosure, the semiconductor substrate 100 selects the silicon substrate.

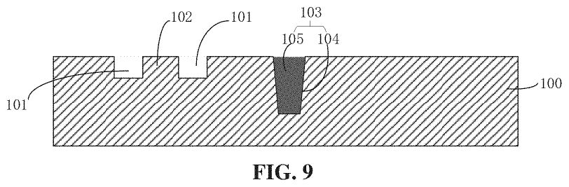

As shown in FIG. 9, in S200, a plurality of grooves 101 arranged at intervals and a shallow trench isolation structure 103 are formed on the semiconductor substrate 100, and a substrate bulge 102 is formed between two adjacent grooves 101.

As shown in FIG. 2-FIG. 9, the grooves 101 and the shallow trench isolation structure 103 are formed on the semiconductor substrate 100, and the substrate bulge 102 is formed between two adjacent grooves 101. In the disclosure, no limitation is made to the numbers of the grooves 101 and the shallow trench isolation structures 103.

As shown in FIG. 2-FIG. 9, in some embodiments of the disclosure, S200 includes the following operations.

At S210, a mask layer 110, an anti-reflection layer 120 and a first patterned photoetching layer 130 are successively formed on the semiconductor substrate 100.

At S220, the first photoetching layer 130 is used as a mask to etch part of the anti-reflection layer 120, and a plurality of bulges 121 arranged at intervals are formed on the anti-reflection layer 120.

At S230, the first photoetching layer 130 is removed, to form a second patterned photoetching layer 140 on the anti-reflection layer 120, and the second photoetching layer 140 does not cover the bulges 121 on the anti-reflection layer 120.

At S240, the second photoetching layer 140 is used as the mask to etch part of the mask layer 110 and part of the semiconductor substrate 100, and the plurality of grooves 101 arranged at intervals and an isolation channel 104 are formed on the semiconductor substrate 100.

At S250, a dielectric layer is deposited in the isolation channel 104, and the dielectric layer and the isolation channel 104 form a shallow trench isolation structure 103.

As shown in FIG. 2-FIG. 4, in S210, the mask layer 110, the anti-reflection layer 120 and the first patterned photoetching layer 130 are successively formed on the surface of the semiconductor substrate 100.

As shown in FIG. 2, the mask layer 110 is formed on the surface of the semiconductor substrate 100, and the mask layer 110 covers the upper surface of the semiconductor substrate 100. The mask layer 110 is formed by adopting a chemical vapor deposition method, an atomic layer deposition method or a physical vapor deposition method. In the disclosure, no limitation is made to the method for forming the mask layer 110, and the specific method may be selected by those skilled in the art according to the actual demands.

In some embodiments of the disclosure, the material of the mask layer 110 may be selected from any one or more of carbon, silicon, compound of carbon and silicon and other suitable materials, for example, silicon dioxide (SiO₂), silicon nitride (SiN), silicon oxynitride (SiON), α-Si, etc. No limitation is made herein. In the disclosure, the mask layer 110 may include a multi-layer structure. As shown in FIG. 2, the mask layer 110 successively includes a silicon dioxide layer 111 formed on the surface of the semiconductor substrate 100, a silicon nitride layer 112 formed on the surface of the silicon dioxide layer 111, a carbon layer 113 formed on the surface of the silicon nitride layer 112 and an α-Si layer 114 formed on the surface of the carbon layer 113, etc. Certainly, the mask layer 110 may include a multi-layer silicon dioxide layer or silicon nitride layer, or include other material layers, and no limitation is made herein. In some embodiments of the disclosure, the mask layer 110 further includes a SOC layer 115. It is to be noted that the disclosure does not make a limitation to the specific content of the multi-layer structure included in the mask layer 10.

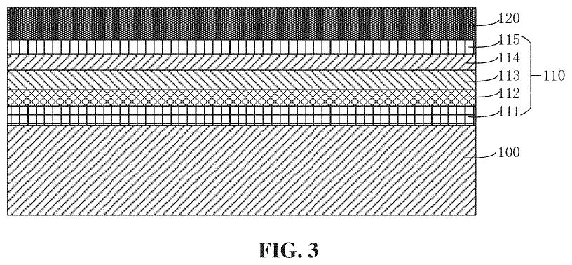

As shown in FIG. 3, the anti-reflection layer 120 is formed on the surface of the mask layer 110. The anti-reflection layer 120 covers the upper surface of the mask layer 110. In the embodiment of FIG. 3, the anti-reflection layer 120 covers the upper surface of the SOC layer 115. The material of the anti-reflection layer 120 is selected from an organic anti-reflection material or an inorganic anti-reflection material. Herein, the inorganic anti-reflection material may be selected from TiO₂, TiN, a-Si and the like, and the organic anti-reflection material may be selected from one or more organic polymers, such as a glucan ester polymer, etc.

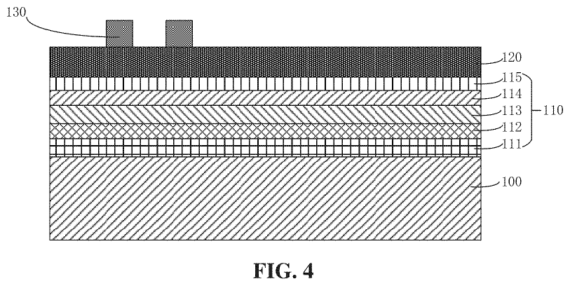

As shown in FIG. 4, the first photoetching layer 130 is formed on the surface of an anti-reflection layer 120. The first photoetching layer 130 covers the upper surface of the anti-reflection layer 120.

In S220, the first photoetching layer 130 is used as the mask to etch part of the anti-reflection layer 120, to form the plurality of bulges 121 arranged at intervals on the anti-reflection layer 120.

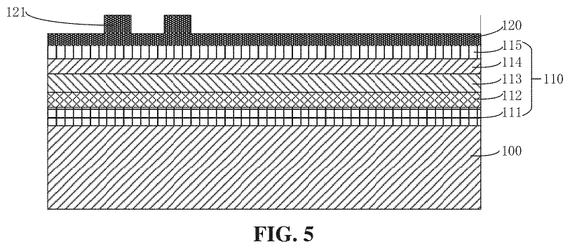

As shown in FIG. 4 and FIG. 5, the first photoetching layer 130 covers part of the anti-reflection layer 120, the first photoetching layer 130 is used as the mask to etch the anti-reflection layer 120, and the plurality of bulges 121 arranged at intervals are formed on locations corresponding to the first photoetching layer 130, on the anti-reflection layer 120. In this step, the height of the formed bulges 121 affects the length of the semiconductor device subsequently formed. In the etching process, the height of the formed bulges 121 may be set according to the actual demands.

In S230, the first photoetching layer 130 is removed, a second patterned photoetching layer 140 is formed on the anti-reflection layer 120, and the second photoetching layer 140 does not cover the bulges 121 on the anti-reflection layer 120.

In this step, the structure in which the first photoetching layer 130 is removed is as shown in FIG. 5. The plurality of bulges 121 arranged at intervals are formed on the anti-reflection layer 120.

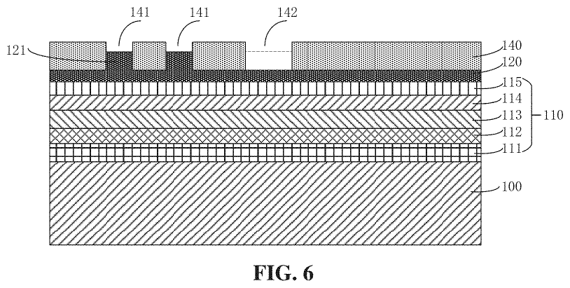

As shown in FIG. 6, the second patterned photoetching layer 140 is formed on the anti-reflection layer 120. The second photoetching layer 140 does not cover the bulges 121 on the anti-reflection layer 120. In some embodiments of the disclosure, the second photoetching layer 140 has a plurality of first openings 141 that are arranged at intervals and a second opening 142. The first openings 141 expose the upper surface of the bulges 121 on the anti-reflection layer 120, and the second opening 142 exposes part of the anti-reflection layer 120.

In S240, the second photoetching layer 140 is used as the mask to etch part of the mask layer 110 and part of the semiconductor substrate 100, and the plurality of grooves 101 arranged at intervals and the isolation channel 104 are formed on the semiconductor substrate 100.

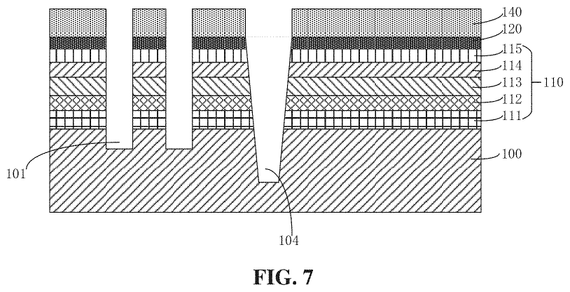

As shown in FIG. 7, the second photoetching layer 140 is used as the mask to etch part of the mask layer 110 and part of the semiconductor substrate 100, and the grooves 101 and the isolation channel 104 are formed on the semiconductor substrate 100. The positions of the grooves 101 correspond to those of the first openings 141, and the position of the isolation channel 104 correspond to the second opening 142.

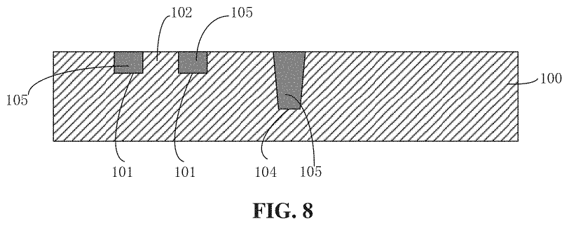

As shown in FIG. 6 and FIG. 8, in some embodiments of the disclosure, the depth of the isolation channel 104 is greater than the depth of the grooves 101. The depth of the grooves 101 depends on the depth of the isolation channel 104 and the height of the bulges 121 formed on the anti-reflection layer 120. The depth of the grooves 101 is set according to the specific actual demands, and in this embodiment, the depth of the grooves 101 is 5-10 nm.

In S250, the dielectric layer are deposited in the isolation channels 104, and the dielectric layer and the isolation channel 104 form a shallow trench isolation structure 103.

As shown in FIG. 8 and FIG. 9, the plurality of grooves 101 and the isolation channel 104 are provided in the formed semiconductor substrate 100, and the isolation channel 104 is configured to subsequently form the shallow trench isolation structure 103. S250 includes: the dielectric layer 105 is deposited in the grooves 101 and the isolation channel 104 to form a structure as shown in FIG. 8, the dielectric layer 105 is flattened by adopting a Chemical Mechanical Polishing (CMP) process, a photoetching glue layer is deposited so as to cover the dielectric layer 105 in the isolation channel 104, and the dielectric layer 105 in the grooves 101 are removed so as to form a structure as shown in FIG. 9. The dielectric layer 105 in the isolation channel 104 and the isolation channel 104 form the shallow trench isolation structure 103.

In S300, the gate oxide layer 150 is deposited on the surface of the semiconductor substrate 100, and the gate oxide layer 150 covers the grooves 101 and the substrate bulge 102.

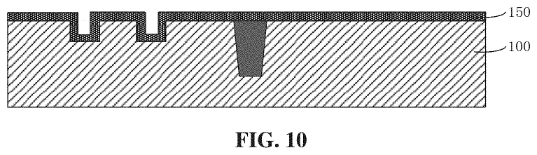

As shown in FIG. 10, the gate oxide layer 150 is deposited on the surface of the semiconductor substrate 100 formed with the grooves 101 and the shallow trench isolation structure 103, and the gate oxide layer 150 covers the grooves 101 and the substrate bulge 102. The gate oxide layer 150 covers the side walls and upper surface of the substrate bulge 102. The material of the gate oxide layer 150 may be selected from silicon oxide, such as SiO₂.

In S400, a gate structure is formed on the gate oxide layer 150, the gate structure includes a first gate structure 10a and a second gate structure 10b, and the first gate structure 10a covers the surface of the substrate bulge 102.

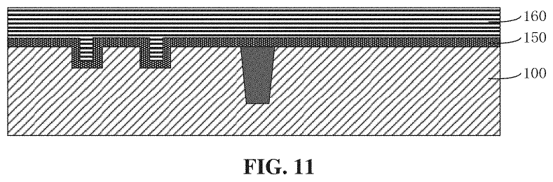

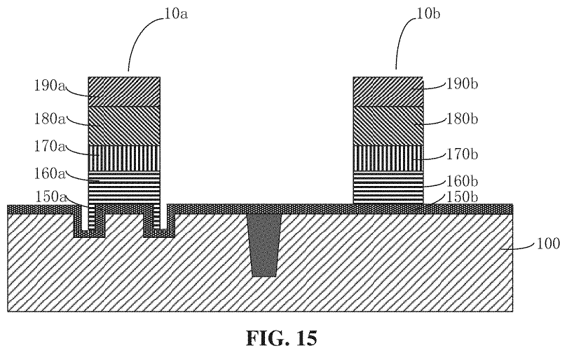

As shown in FIG. 11-FIG. 15, the gate structure is formed on the gate oxide layer 150. In the embodiment shown in FIG. 15, the first gate structure 10a is formed on the gate oxide layer 150 at one side of the shallow trench isolation structure 103, and the second gate structure 10b is formed on the gate oxide layer 150 at the other side of the shallow trench isolation structure 103. The first gate structure 10a covers the surface of the substrate bulge 102. The first gate structure 10a covers the side walls and upper surface of the substrate bulge 102. In a transistor device subsequently formed, a bending conductive channel may be formed on the surface of the substrate bulge 102 covered by the first gate structure 10a, and the trench length of the transistor device is longitudinally stretched, thereby improving the capacitance parameter of the transistor device and effectively improving the short-channel effect.

In some embodiments of the disclosure, S400 includes the following operations.

At S410, a polycrystalline silicon layer 160 is formed on the gate oxide layer 150, and the polycrystalline silicon layer 160 covers the surface of the gate oxide layer 150.

At S420, a barrier layer 170 is formed on the polycrystalline silicon layer 160, and the barrier layer 170 covers the surface of the polycrystalline silicon layer 160.

At S430, a conductive metal layer 180 is formed on the barrier layer 170, and the conductive metal layer 180 covers the surface of the barrier layer 170.

At S440, an insulation layer 190 is formed on the conductive metal layer 180, and the insulation layer 190 covers the surface of the conductive metal layer 180.

At S450, part of the polycrystalline silicon layer 160, part of the barrier layer 170, part of the conductive metal layer 180 and part of the insulation layer 190 are etched to form the gate structure.

In S410, as shown in FIG. 11, the polycrystalline silicon layer 160 is formed on the gate oxide layer 150, and the polycrystalline silicon layer 160 covers the surface of the gate oxide layer 150.

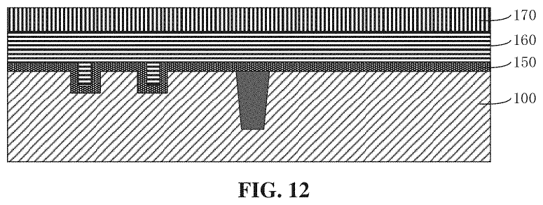

In S420, as shown in FIG. 12, the barrier layer 170 is formed on the polycrystalline silicon layer 160, and the barrier layer 170 covers the surface of the polycrystalline silicon layer 160. The material of the barrier layer 170 may be selected from nitride, oxide or other types of conductive materials, such as titanium nitride. No specific limitation is made thereto.

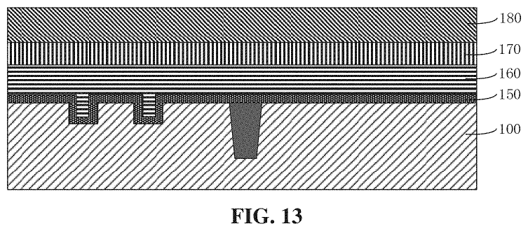

In S430, as shown in FIG. 13, the conductive metal layer 180 is formed on the barrier layer 170, and the conductive metal layer 180 covers the surface of the barrier layer 170. The material of the conductive metal layer 180 is selected from metal, metal oxide, metal nitride, metal silicide and the like, such as tungsten, titanium, nickel or an alloy manufactured by metal and polycrystalline silicon. No specific limitation is made thereto.

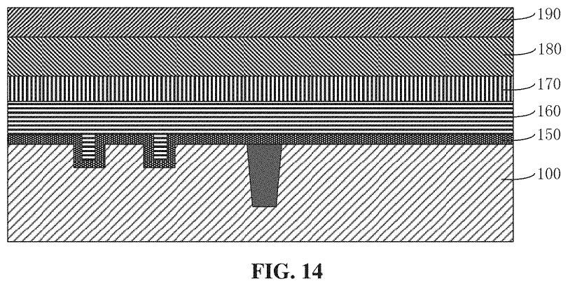

In S440, as shown in FIG. 14, the insulation layer 190 is formed on the conductive metal layer 180, and the insulation layer 190 covers the surface of the conductive metal layer 180. The material of the insulation layer 190 is selected from oxide or nitride, such as silicon nitride, silicon oxide. No specific limitation is made thereto.

In S450, as shown in FIG. 15, part of the polycrystalline silicon layer 160, part of the barrier layer 170, part of the conductive metal layer 180 and part of the insulation layer 190 are etched to form the gate structure. A third photoetching layer may be formed on the surface of the insulation layer 190. The third photoetching layer is used as the mask to successively etch part of the insulation layer 190, part of the conductive metal layer 180, part of the barrier layer 170 and part of the polycrystalline silicon layer 160, and thus the gate structure is formed. The gate structure includes a first gate structure 10a and a second gate structure 10b. After etching, a first insulation layer 190a and a second insulation layer 190b are formed in an area, covered by the third photoetching layer, in the insulation layer 190. A first conductive metal layer 180a and a second conductive metal layer 180b are formed in an area, covered by the third photoetching layer, in the conductive metal layer 180. A first barrier layer 170a and a second barrier layer 170b are formed in an area, covered by the third photoetching layer, in the barrier layer 170. A first polycrystalline silicon layer 160a and a second polycrystalline silicon layer 160b are formed in an area, covered by the third photoetching area, in the polycrystalline silicon layer 160. The first gate structure 10a includes the first polycrystalline silicon layer 160a, the first barrier layer 170a, the first conductive metal layer 180a and the first insulation layer 190a. The second gate structure 10b includes the second polycrystalline silicon layer 160b, the second barrier layer 170b, the second conductive metal layer 180b and the second insulation layer 190b. The first gate structure 10a is located at one side of the shallow trench isolation structure 103, the second gate structure 10b is located at the other side of the shallow trench isolation structure 103, and the first gate structure 10a covers the surface of the substrate bulge 102. It is to be noted that, in the gate oxide layer 150, a first gate oxide layer 150a is formed in an area covered by the first polycrystalline silicon layer 160a, and a second gate oxide layer 150b is formed in an area covered by the second polycrystalline silicon layer 160b, for subsequent manufacturing and forming of the transistor device. In another embodiment, the third photoetching layer may also be used as the mask to directly etch the gate oxide layer 150, so that the first gate oxide layer 150a corresponding to the first polycrystalline silicon layer 160a, and the second gate oxide layer 150b corresponding to the second polycrystalline silicon layer 160b are formed.

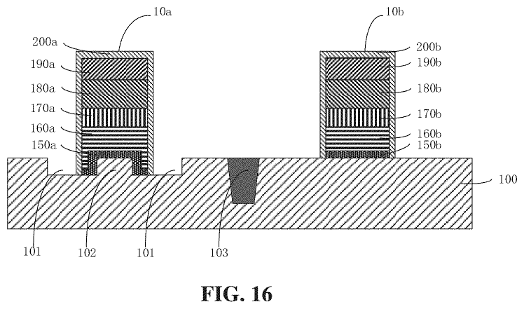

In some embodiments of the disclosure, after forming the gate structure, an isolation layer 200 is covered on the gate structure. As shown in FIG. 16, the isolation layer 200 at least covers the side wall of the gate structure, or covers the side wall and upper surface of the gate structure, so as to avoid exposing the side wall of the gate structure. The material of the isolation layer 200 may be silicon nitride. What covers the first gate structure 10a is a first isolation layer 200a, and what covers the second gate structure 10b is a second isolation layer 200b.

In S500, the source electrode and the drain electrode are formed in the semiconductor substrate 100, and the gate oxide layer 150, the gate structure, the source electrode and the drain electrode form the transistor device.

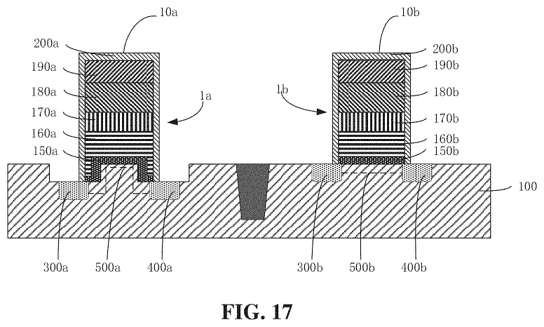

In some embodiments of the disclosure, ions are injected to the semiconductor substrate 100 by using an ion injection technique, so as to form the source electrode and the drain electrode. As shown in FIG. 17, a source area and a drain area are formed at the two sides of the gate structure in the substrate 100 by adopting the ion injection technique, and the source electrode and the drain electrode are formed in the source area and the drain area respectively. The gate oxide layer 150, the gate structure, the source electrode and the drain electrode form the transistor device. The transistor device includes a first transistor device 1a and a second transistor device 1b, the first transistor device 1a includes a first gate structure 10a, and the second transistor device 1b includes a second gate structure 10b. Herein, the source area and the drain area extend below the gate structure, namely, the gate structure can overlap with the height projections of the source area and the drain area, so that the control on the current implemented through the gate structure is ensured, and then the performance of the manufactured transistor device is ensured.

Still as shown in FIG. 17, a channel is formed between the source area and the drain area and along a boundary area of the gate structure. The source area includes a first source area 300a located below the first gate structure 10a and a second source area 300b located blow the second gate structure 10b. The drain area includes a second drain area 400b located below the first gate structure 10a and a second drain area 400b located below the second gate structure 10b. A first conductive channel 500a is formed between the first source area 300a and the first drain area 400a and along the boundary area of the first gate structure 10a. A second conductive channel 500b is formed between the second source area 300b and the second drain area 400b and along the boundary area of the second gate structure 10b. The formed first conductive channel 500a is shown as a curved dotted line in FIG. 17, and the formed second conductive channel 500b is shown as a straight dotted line in FIG. 17. The first conductive channel 500a formed in the first gate structure 10a extends in a longitudinal direction (a direction perpendicular to the semiconductor substrate 100). Compared with the traditional straight conductive channel, under the same horizontal (parallel to the semiconductor substrate 100) length, the length of the conductive channel is greater than that of the straight conductive channel, so that the capacitance parameter of the transistor device may be effectively adjusted, thereby helping reduce the short-channel effect of the transistor device.

Still as shown in FIG. 17, in some embodiments of the disclosure, the semiconductor device including the first transistor device 1a and the second transistor device 1b is manufactured by the above method for manufacturing the semiconductor device, the first conductive channel 500a formed by the first transistor device 1a is a bending structure, and the second conductive channel 500b formed by the second transistor device 1b is a linear type. The conductive channel with the bending structure is longer than the linear type conductive channel, which is beneficial to adjust the capacitance parameter of the corresponding transistor device, adjust the electrical performance of the transistor device to reach the requirements, improve the short-channel effect of the transistor device and ensure the yield of the semiconductor device. In addition, in the above method of the disclosure, the grooves 101 are formed while forming the isolation channel 104, and when forming the gate oxide layer 150, only one deposition process is required. Compared with providing the semiconductor device with different capacitance parameters by changing the thickness of the oxide layer in the related art, the method of the disclosure reduces the deposition times for forming the gate oxide layer 150, further simplifies the process and reduces the manufacturing cost.

As shown in FIG. 16 and FIG. 17, the disclosure further provides a semiconductor device, which includes a semiconductor substrate 100, a gate oxide layer, a gate structure, a source electrode and a drain electrode. A plurality of grooves 101 arranged at intervals and a shallow trench isolation structure 103 are formed on the semiconductor substrate 100, and a substrate bulge 102 is formed between two adjacent grooves 101. The gate oxide layer is deposited on the surface of the semiconductor substrate 100, and the gate oxide layer covers the grooves 101 and the substrate bulge 102. The gate structure is formed on the gate oxide layer, the gate structure includes a first gate structure 10a and a second gate structure 10b, and the first gate structure 10a covers the surface of the substrate bulge 102. The source electrode and the drain electrode are formed in the semiconductor substrate 100. The gate oxide layer, the gate structure, the source electrode and the drain electrode form the transistor device, the transistor device includes a first transistor device 1a and a second transistor device 1b, and the first transistor device 1a includes a first gate structure 10a.

As shown in FIG. 16 and FIG. 17, the gate oxide layer includes a first gate oxide layer 150a located at one side of the shallow trench isolation structure 103 and a second gate oxide layer 150b formed at the other side of the shallow trench isolation structure 103. The first gate oxide layer 150a covers the grooves 101 and the substrate bulge 102. A first source area 300a and a first drain area 400a are respectively formed at the two sides of the first gate structure 10a in the semiconductor substrate 100, the first source area 300a and the first drain area 400a extend below the first gate structure 10a, namely, the first gate structure 10a can overlap with the height projections of the first source area 300a and the first drain area 400a, so that the control of the current can be implemented through the first gate structure 10a. A second source area 300b and a second drain area 400b are respectively formed at the two sides of the second gate structure 10b in the semiconductor substrate 100. The second source area 300b and the second drain area 400b extend below the second gate structure 10b, namely, the second gate structure 10b can r overlap with the height projections of the second source area 300b and the second drain area 400b, so that the control of the current can be implemented through the second gate structure 10b. The source electrode includes a first source electrode and a second source electrode, which are respectively formed in the first source area 300a and the second source area 300b. The drain electrode includes a first drain electrode and a second drain electrode, which are respectively formed in the first drain area 400a and the second drain area 400b. The first gate oxide layer 150a, the first gate structure 10a, the first source electrode and the first drain electrode form the first transistor device 1a. The second gate oxide layer 150b, the second gate structure 10b, the second source electrode and the second drain electrode form the second transistor device 1b. In some embodiments, the transistor device further includes an isolation layer formed on the gate structure, and the isolation layer at least covers the side wall of the gate structure. As shown in FIG. 17, the isolation layer includes a first isolation layer 200a covering the first gate structure 10a and a second isolation layer 200b covering the second gate structure 10b. The first transistor device 1a further includes a first isolation layer 200a, and the second transistor device 1b further includes a second isolation layer 200b. The first conductive channel 500a formed by the first transistor device 1a is a bending structure, and the second conductive channel 500b formed by the second transistor device 1b is a linear type. The conductive channel with the bending structure is longer than the linear type conductive channel, which is beneficial to adjust the capacitance parameter of the corresponding transistor device, adjust the electrical performance of the transistor device to reach the requirements, improve the short-channel effect of the transistor device and ensure the yield of the semiconductor device.

In some embodiments of the disclosure, the gate structure includes a polycrystalline silicon layer, a barrier layer, a conductive metal layer and an insulation layer. The polycrystalline silicon layer is formed on the gate oxide layer and covers the surface of the gate oxide layer. The barrier layer is formed on the polycrystalline silicon layer and covers the surface of the polycrystalline silicon layer. The conductive metal layer is formed on the barrier layer and covers the surface of the barrier layer. The insulation layer is formed on the conductive metal layer and covers the surface of the conductive metal layer. As shown in FIG. 17, the first gate structure 10a includes the first polycrystalline silicon layer 160a, the first barrier layer 170a, the first conductive metal layer 180a and the first insulation layer 190a. The second gate structure 10b includes the second polycrystalline silicon layer 160b, the second barrier layer 170b, the second conductive metal layer 180b and the second insulation layer 190b.

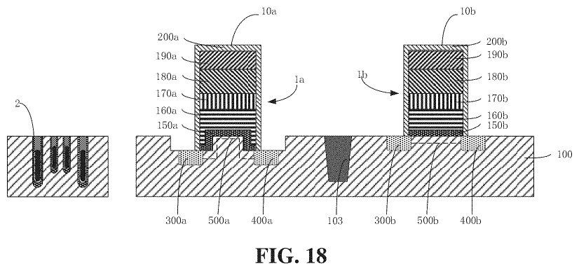

The disclosure further provides a memory, which includes a semiconductor device manufactured by the manufacturing method of the disclosure. As shown in FIG. 18, the memory includes an array area and a peripheral area. The array area includes an embedding transistor device 2, and the embedding transistor may adopt any similar transistor device suitable for the related art. The specific structure is not described in details herein. The peripheral area includes a semiconductor device manufactured by the disclosure, and includes a first transistor device 1a and a second transistor device 1b.

It needs to be noted that although various steps of the methods in the disclosure are described in a particular order in the drawing, it is not required or implied that those steps must be performed in that particular order, or that all of the steps shown must be performed to achieve the desired result. Additional or alternative steps, omission of certain steps, combination of a plurality of steps into a single step, and/or decomposition of a step into a plurality of steps, shall be considered part of the disclosure.

It should be understood that the disclosure does not limit its application to the detailed structure and arrangement of the components presented in the specification. The disclosure can have other implementation modes and can be implemented and executed in a variety of modes. The abovementioned forms of deformation and modification fall within the scope of the disclosure. It should be understood that the disclosure and limitation of the disclosure extend to all alternative combinations of two or more separate features referred to or evident in the text and/or drawings. All of these different combinations constitute a plurality of alternative aspects of the disclosure. The implementation mode of this specification illustrates the best known mode to implement the disclosure and will enable those skilled in the art to make use of the disclosure.

1. A method for manufacturing a semiconductor device, comprising:
providing a semiconductor substrate;
forming a shallow trench isolation structure and a plurality of grooves arranged at intervals on the semiconductor substrate, and forming a substrate bulge between two adjacent ones of the grooves;
depositing a gate oxide layer on a surface of the semiconductor substrate, to cover the grooves and the substrate bulge;
forming a gate structure on the gate oxide layer, the gate structure comprising a first gate structure and a second gate structure, and the first gate structure covering a surface of the substrate bulge; and
forming a source electrode and a drain electrode in the semiconductor substrate, wherein the gate oxide layer, the gate structure, the source electrode and the drain electrode form a transistor device.

2. The method for manufacturing the semiconductor device of claim 1, wherein the transistor device comprises a first transistor device and a second transistor device, and the first transistor device comprises a first gate structure.

3. The method for manufacturing the semiconductor device of claim 2, wherein the first transistor device is located at one side of the shallow trench isolation structure, and the second transistor device is located at another side of the shallow trench isolation structure.

4. The method for manufacturing the semiconductor device of claim 1, wherein forming the gate structure on the gate oxide layer comprises:
forming a polycrystalline silicon layer on the gate oxide layer, to cover a surface of the gate oxide layer;
forming a barrier layer on the polycrystalline silicon layer, to cover a surface of the polycrystalline silicon layer;
forming a conductive metal layer on the barrier layer, to cover a surface of the barrier layer;
forming an insulation layer on the conductive metal layer, to cover a surface of the conductive metal layer; and
etching part of the polycrystalline silicon layer, part of the barrier layer, part of the conductive metal layer and part of the insulation layer to form the gate structure.

5. The method for manufacturing the semiconductor device of claim 1, wherein forming the source electrode and the drain electrode in the semiconductor substrate comprises:
injecting ions to the semiconductor substrate by using an ion injection technique, to form the source electrode and the drain electrode.

6. The method for manufacturing the semiconductor device of claim 1, wherein forming the shallow trench isolation structure and the plurality of grooves arranged at intervals comprises:
successively forming a mask layer, an anti-reflection layer and a first patterned photoetching layer on the semiconductor substrate;
taking the first patterned photoetching layer as a mask to etch part of the anti-reflection layer, to form a plurality of bulges arranged at intervals on the anti-reflection layer;
removing the first patterned photoetching layer, to form a second patterned photoetching layer on the anti-reflection layer, the second patterned photoetching layer not covering the bulges on the anti-reflection layer;
taking the second patterned photoetching layer as the mask to etch part of the mask layer and part of the semiconductor substrate, to form the plurality of grooves and isolation channels arranged at intervals on the semiconductor substrate; and
depositing a dielectric layer in the isolation channels, the dielectric layer and the isolation channels forming the shallow trench isolation structure.

7. A semiconductor device, comprising:
a semiconductor substrate, comprising a shallow trench isolation structure and a plurality of grooves arranged at intervals, wherein a substrate bulge is formed between two adjacent ones of the grooves;
a gate oxide layer, deposited on a surface of the semiconductor substrate, and the gate oxide layer covering the grooves and the substrate bulge;
a gate structure, formed on the gate oxide layer, wherein the gate structure comprises a first gate structure and a second gate structure, and the first gate structure covers a surface of the substrate bulge; and
a source electrode and a drain electrode, formed in the semiconductor substrate.

8. The semiconductor device of claim 7, wherein the gate structure comprises:
a polycrystalline silicon layer, formed on the gate oxide layer and covering a surface of the gate oxide layer;
a barrier layer, formed on the polycrystalline silicon layer and covering a surface of the polycrystalline silicon layer;
a conductive metal layer, formed on the barrier layer and covering a surface of the barrier layer; and
an insulation layer, formed on the conductive metal layer and covering a surface of the conductive metal layer.

9. The semiconductor device of claim 7, wherein the gate oxide layer, the gate structure, the source electrode, and the drain electrode form a transistor device, the transistor device comprises a first transistor device and a second transistor device, the first transistor device comprises the first gate structure, and the second transistor device comprises the second gate structure.

10. The semiconductor device of claim 7, wherein the gate oxide layer includes a first gate oxide layer located at one side of the shallow trench isolation structure and a second gate oxide layer formed at another side of the shallow trench isolation structure.

11. The semiconductor device of claim 9, wherein a first source area is formed on one side of the first gate structure, a first drain area is formed on another side of the first gate structure, and the first source area and the first drain area extend below the first gate structure; and
a second source area is formed on one side of the second gate structure, a second drain area is formed at another side of the second gate structure, and the second source area and the second drain area extend below the second gate structure.

12. The semiconductor device of claim 9, wherein the semiconductor device further comprises an isolation layer formed on the gate structure and at least covering side walls of the gate structure, and the isolation layer includes a first isolation layer covering the first gate structure and a second isolation layer covering the second gate structure.

13. The semiconductor device of claim 9, wherein a first conductive channel formed by the first transistor device is a bending structure, and a second conductive channel formed by the second transistor device is a linear type, the first conductive channel is longer than the second conductive channel.

14. A memory, comprising an array area and a peripheral area, wherein the peripheral area comprises a semiconductor device, wherein the semiconductor device comprises:
a semiconductor substrate, comprising a shallow trench isolation structure and a plurality of grooves arranged at intervals, wherein a substrate bulge is formed between two adjacent ones of the grooves;
a gate oxide layer, deposited on a surface of the semiconductor substrate, and the gate oxide layer covering the grooves and the substrate bulge;
a gate structure, formed on the gate oxide layer, wherein the gate structure comprises a first gate structure and a second gate structure, and the first gate structure covers a surface of the substrate bulge; and
a source electrode and a drain electrode, formed in the semiconductor substrate.

15. The memory of claim 14, wherein the gate structure comprises:
a polycrystalline silicon layer, formed on the gate oxide layer and covering a surface of the gate oxide layer;
a barrier layer, formed on the polycrystalline silicon layer and covering a surface of the polycrystalline silicon layer;
a conductive metal layer, formed on the barrier layer and covering a surface of the barrier layer; and
an insulation layer, formed on the conductive metal layer and covering a surface of the conductive metal layer.

16. The memory of claim 14, wherein the gate oxide layer, the gate structure, the source electrode, and the drain electrode form a transistor device, the transistor device comprises a first transistor device and a second transistor device, and the first transistor device comprises the first gate structure, and the second transistor device comprises the second gate structure.

17. The memory of claim 14, wherein the gate oxide layer includes a first gate oxide layer located at one side of the shallow trench isolation structure and a second gate oxide layer formed at another side of the shallow trench isolation structure.

18. The memory of claim 16, wherein a first source area is formed on one side of the first gate structure, a first drain area is formed on another side of the first gate structure, and the first source area and the first drain area extend below the first gate structure; and
a second source area is formed on one side of the second gate structure, a second drain area is formed at another side of the second gate structure, and the second source area and the second drain area extend below the second gate structure.

19. The memory of claim 16, wherein the semiconductor device further comprises an isolation layer formed on the gate structure and at least covering side walls of the gate structure, and the isolation layer includes a first isolation layer covering the first gate structure and a second isolation layer covering the second gate structure.

20. The memory of claim 16, wherein a first conductive channel formed by the first transistor device is a bending structure, and a second conductive channel formed by the second transistor device is a linear type, the first conductive channel is longer than the second conductive channel.
